(19) United States
(12) Patent Application Publication
(10) Pub. No.: US 2009/0072400 A1
(43) Pub. Date: Mar. 19, 2009

(54) CONTACT FORMING IN TWO PORTIONS AND CONTACT SO FORMED

(75) Inventors: Huilong Zhu, Poughkeepsie, NY (US); James J. Heaps-Nelson, Chandler, AZ (US); Mahender Kumar, Fishkill, NY (US); Christine Norris, Stamford, CT (US); Ravikumar Ramachandran, Pleasantville, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/856,839

(22) Filed: Sep. 18, 2007

(51) Int. Cl. H01L 23/52; H01L 21/44

(52) U.S. Cl. 257/751; 438/653; 257/E23.141; 257/E21.476

(57) ABSTRACT

Methods of forming a contact in two or more portions and a contact so formed are disclosed. One method includes providing a device including a silicide region; and forming a contact to the silicide region by: first forming a lower contact portion to the silicide region through a first dielectric layer, and second forming an upper contact portion to the lower contact portion through a second dielectric layer over the first dielectric layer. A contact may include a first contact portion contacting a silicide region, the first contact portion having a width less than 100 nm; and a second contact portion coupled to the first contact portion from above, the second contact portion having a width greater than the width of the first contact portion.

### BACKGROUND

1. Technical Field

The disclosure relates generally to integrated circuit (IC) chip fabrication, and more particularly, to methods of forming a contact in two or more portions, and a resulting contact.

2. Background Art

As integrated circuit (IC) chip size continues to become smaller, contacts between layers of an IC chip must also become smaller. Fabricating increasingly smaller contact openings through dielectric layers using conventional processes presents a number of problems. For example, it requires a high bias for reactive ion etching (RIE) since it is difficult to etch through small contact holes, which causes an undesirable reduction of selectivity (e.g., of silicon oxide) of contact hole RIE. In this case, contact opening RIE processing either causes underetch (with low bias RIE) or overetch (with high bias RIE) of the dielectric layers. Underetch results in contact openings not reaching the silicide regions of the device, and an open circuit when conductive material is deposited to form the contacts. Overetch results in overly large openings at an upper extent of the contact openings, which causes shorts when conductive material is deposited to form the contacts.

### SUMMARY

Methods of forming a contact in two or more portions and a contact so formed are disclosed. One method includes providing a device including a silicide region; and forming a contact to the silicide region by: first forming a lower contact portion to the silicide region through a first dielectric layer, and second forming an upper contact portion to the lower contact portion through a second dielectric layer over the first dielectric layer. A contact may include a first contact portion contacting a silicide region, the first contact portion having a width less than 100 nm; and a second contact portion coupled to the first contact portion from above, the second contact portion having a width greater than the width of the first contact portion.

A first aspect of the disclosure provides a method of forming a contact, the method comprising: providing a device including a silicide region; depositing a first dielectric layer over the device; forming a first contact opening to the silicide region through the first dielectric layer; depositing a first liner layer in the first contact opening; depositing conductive material to form a first contact portion in the first contact opening; etching to remove the first liner layer outside of the first contact opening; depositing a barrier layer; forming a second dielectric layer; forming a second contact opening in the second dielectric layer to the barrier layer over the first contact portion; removing the barrier layer in the second contact opening; depositing a second liner layer in the second contact opening; and depositing conductive material to form a second contact portion in the second contact opening.

A second aspect of the disclosure provides a contact comprising: a first contact portion contacting a silicide region, the first contact portion having a width less than 100 nm; and a second contact portion coupled to the first contact portion from above, the second contact portion having a width greater than the width of the first contact portion.

A third aspect of the disclosure provides a method of forming a contact, the method comprising: providing a device including a silicide region; and forming a contact to the silicide region by: first forming a lower contact portion to the silicide region through a first dielectric layer, and second forming an upper contact portion to the lower contact portion through a second dielectric layer over the first dielectric layer.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1-13 show embodiments of a method of forming a contact according to the disclosure, with FIG. 13 showing embodiments of a contact according to the disclosure.

FIG. 14 shows an alternative embodiment of the contact according to the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

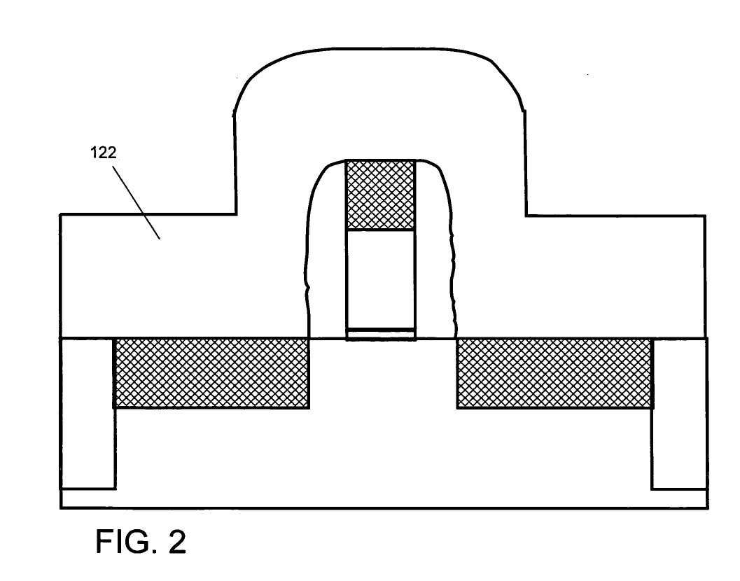

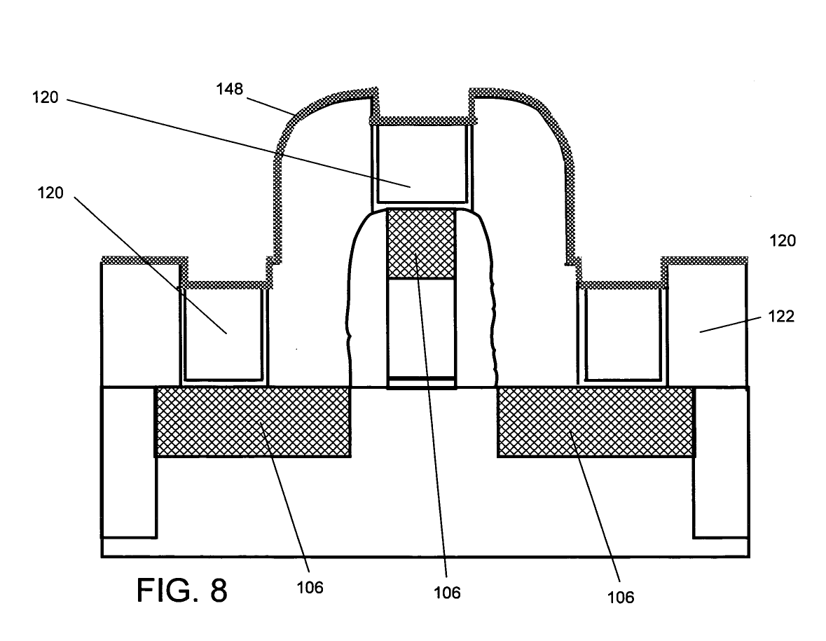

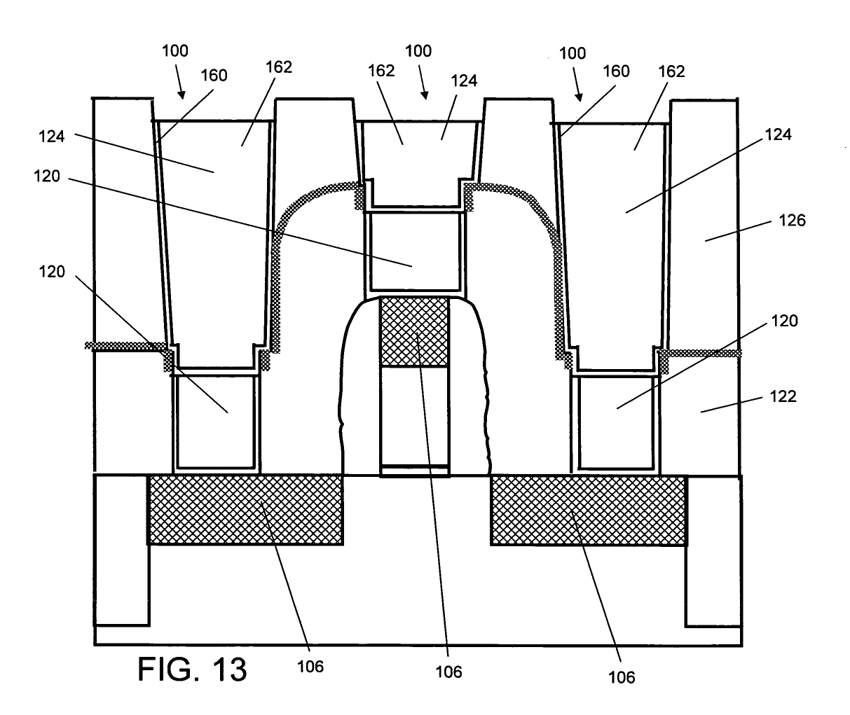

Referring to the drawings, embodiments of a method of forming a contact 100 (FIG. 13) to a silicide region 106 according to the disclosure are shown. As will be described herein in greater detail and with brief reference to FIG. 13, FIGS. 2-7 show forming of a lower contact portion 120 to silicide region 106 through a first dielectric layer 122, and FIGS. 8-13 show forming of an upper contact portion 124 to lower contact portion 120 through a second dielectric layer 126 over first dielectric layer 122.

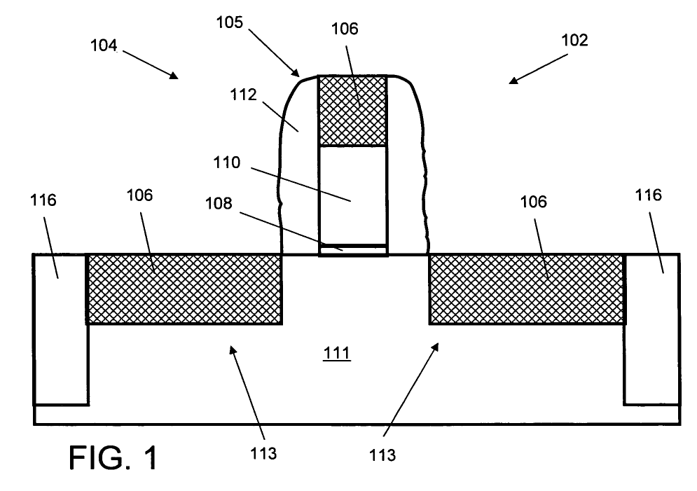

Returning to FIG. 1, an initial structure 102 is provided including a device 104 including silicide region 106 (three shown). Device 104 is shown as a typical metal-oxide semiconductor field effect transistor (MOSFET) 105, but the teachings of the invention are not limited to this type device. Any device including silicide region 106 to be contacted may be used, e.g., transistor, resistor, capacitor, etc. MOSFET 105 includes, among other things, a gate dielectric 108 (e.g., silicon oxide (SiO₂)), a gate body 110 (e.g., doped polysilicon), a spacer 112 (e.g., silicon nitride (Si₃N₄)) and source/drain regions 113 in a silicon substrate 111. Gate body 110 and source/drain regions 113 include silicide regions 106, respectively. Device 104 may be electrically separated from other devices within substrate 111 by trench isolations 116, e.g., of silicon oxide. Three silicide regions 106 are shown; however, device 104 may not always require that number of silicide regions. Silicide region 106 may be formed using any now known or later developed technique, e.g., depositing a metal such as titanium, nickel, cobalt, etc., annealing to have the metal react with silicon, and removing unreacted metal. Other parts of device 104 may be fabricated using any now known or later developed techniques.

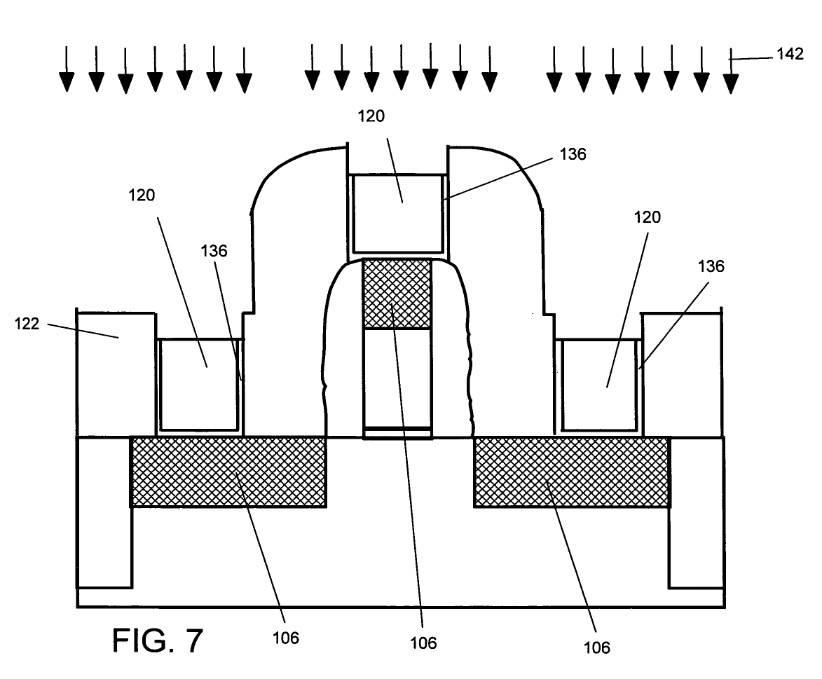

As noted above, FIGS. 2-7 show forming of a lower contact portion 120 (FIG. 7) to silicide region 106 through a first dielectric layer 122. In FIG. 2, a first dielectric layer 122 is deposited over device 104. In one embodiment, first dielectric layer 122 may include silicon nitride (Si₃N₄) or oxynitride, deposited to a depth ranging from approximately 30 nm to approximately 100 nm, ‘approximately’ being ±10% of film thickness. As used herein, “depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

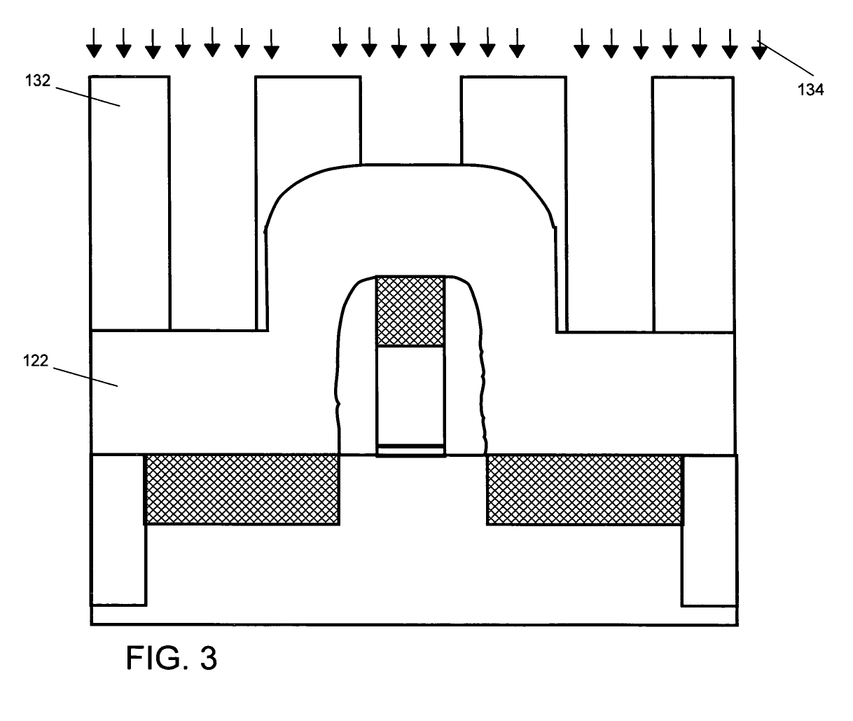

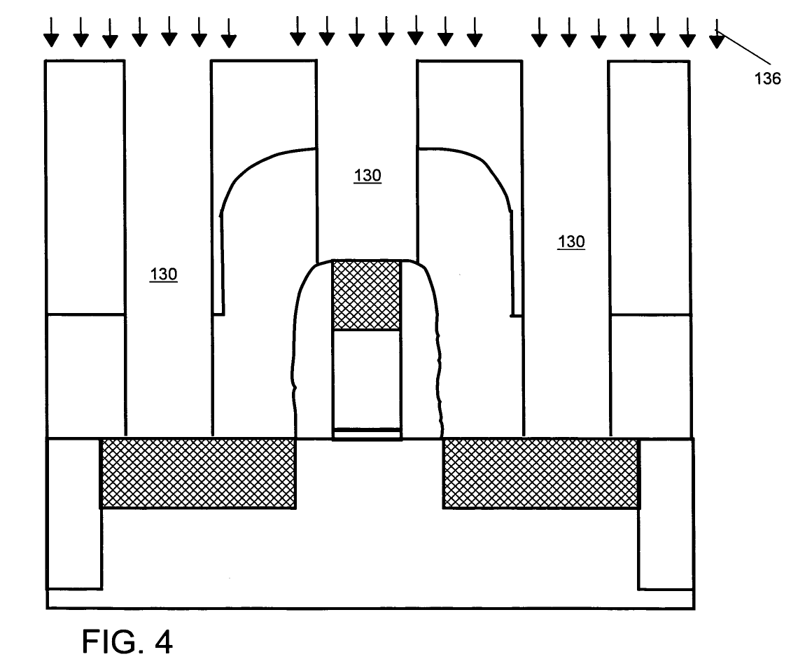

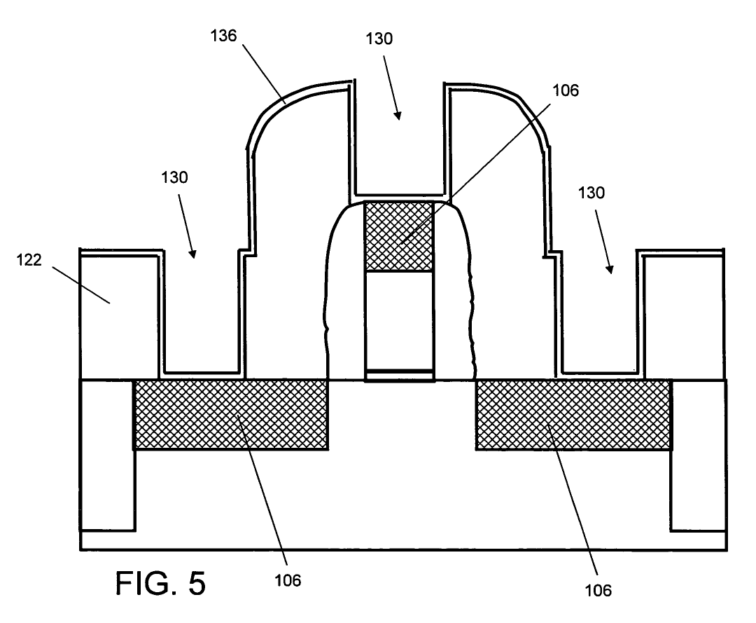

FIGS. 3-4 show forming a first contact opening 130 (FIG. 4) to silicide region 106 through first dielectric layer 122. In FIG. 3, a mask 132 is deposited over first dielectric layer 122 and patterned and etched 134 to form first contact opening 130 (FIG. 4). Mask 132 may include a photoresist or a hardmask, the latter of which may be helpful to avoid oxidation of silicide region 106 due to photoresist removal. If a hardmask is employed, it may be formed from tetraethyl orthosilicate, Si(OC₂H₅)₄ (TEOS) (not shown). (If a hardmask is used, the process may include: depositing thin TEOS or hardmask before spin on resist; patterning the resist and etching the hardmask to transfer the pattern to the hardmask; and removing the resist and then RIE nitride to form first contact opening 130.) Etching 134 may include any appropriate etching recipe to open first dielectric layer 122 to silicide region 106, e.g., a silicon nitride reactive ion etch (RIE). FIG. 4 shows removing mask 132, e.g., using a wet etch 136 (shown removed in FIG. 5 only). First contact opening 130 has a width in the range of approximately 20 nm to approximately 100 nm (‘approximately’ being ±10% of width), which allows for greater contact density compared to conventional processes.

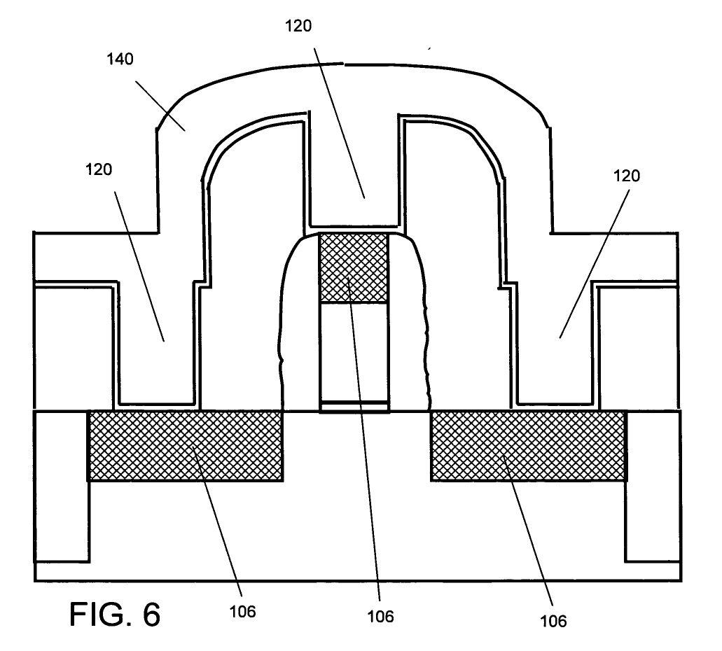

FIG. 5 shows depositing a first liner layer 136 in first contact opening 130. First liner layer 136 may include: titanium nitride (TiN), tantalum nitride (TaN), tantalum (Ta) or titanium (Ti), and may have a thickness ranging from approximately 2 nm to approximately 15 nm. FIG. 6 shows depositing conductive material 140 to form a first contact portion 120 in first contact opening 130 (FIG. 5). Conductive material 140 may be any metal, e.g., chemical vapor deposited (CVD) tungsten, copper plating, or other conductive material typically used for contacts. Conductive material 140, and similarly, first contact portion 120 (without liner layer 136) may have a thickness ranging from approximately 15 nm to approximately 50 nm. FIG. 7 shows etching 142 to remove first liner layer 136 outside of first contact opening 130 (FIG. 5) so first liner 136 does not cause shorts. Conductive material 140 is also etched back during this process. Any appropriate isotropic etch for the respective material may be implemented.

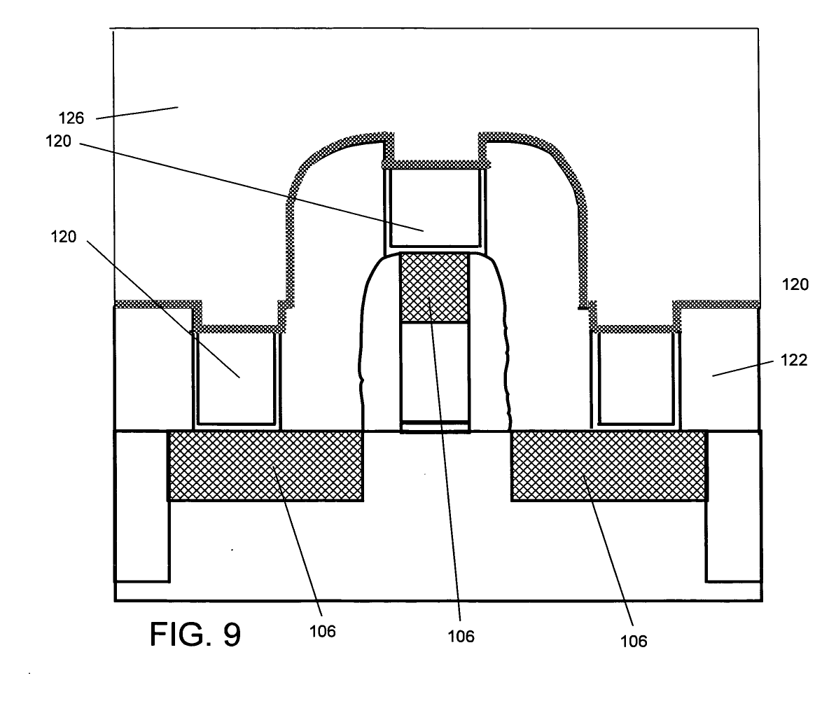

As noted above, FIGS. 8-13 show forming of an upper contact portion 124 (FIG. 13) to lower contact portion 120 through a second dielectric layer 126 (FIGS. 9-13) over first dielectric layer 122. In FIG. 8, a barrier layer 148 is deposited. Barrier layer 148, in one embodiment, includes silicon nitride (Si₃N₄); however, other materials such as oxynitride may be employed.

FIG. 9 shows forming second dielectric layer 126. Second dielectric layer 126 may include, for example, silicon oxide (SiO₂) or other low-k dielectric (k<3.9) such as hydrogenated silicon oxycarbide (SiCOH), porous SiCOH, porous methylsilsesquioxanes (MSQ), porous hydrogensilsesquioxanes (HSQ), octamethylcyclotetrasiloxane (OMCTS) (CH₃)₂SiO—)₄ 2.7 available from Air Liquide, etc. or other low-k dielectrics. A chemical mechanical polishing (CMP) may be required to planarize a surface of second dielectric layer 126.

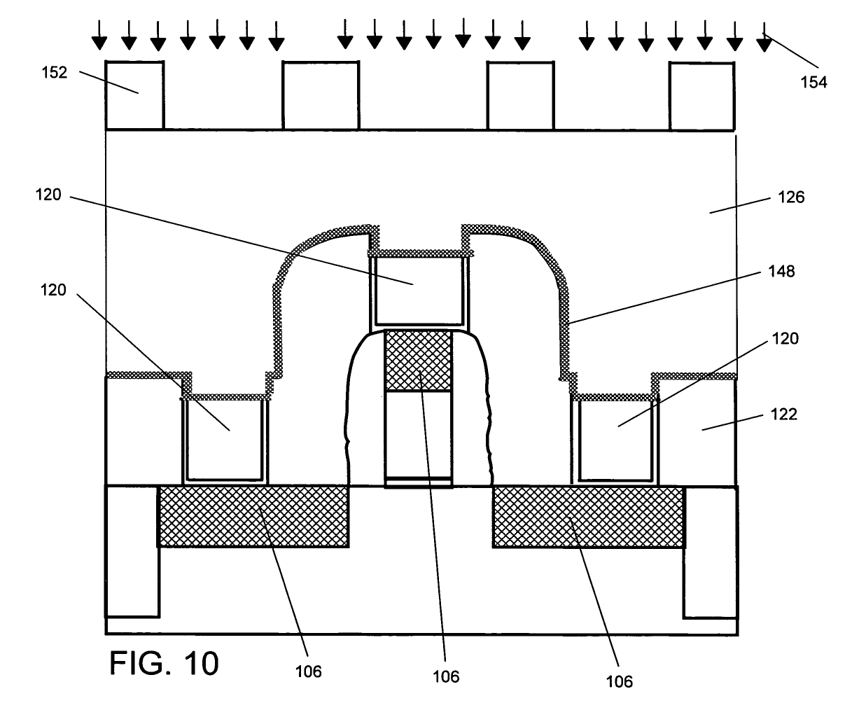

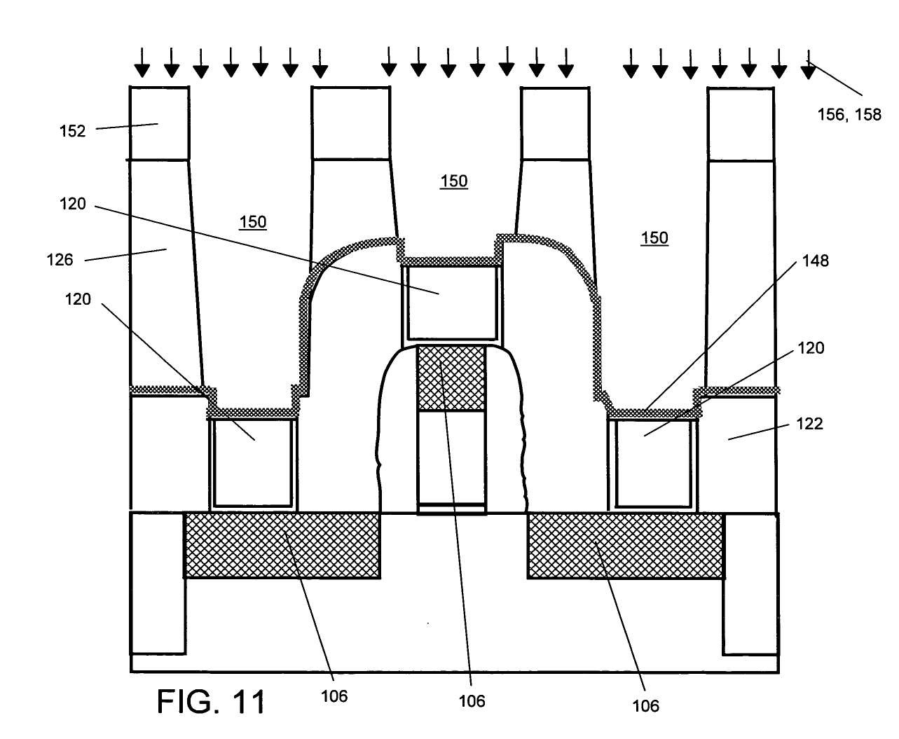

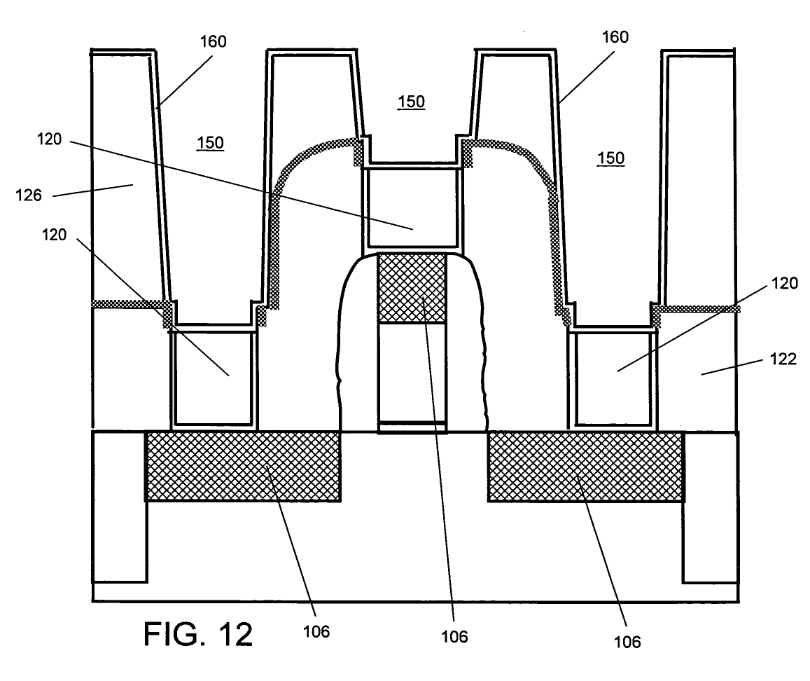

FIGS. 10-11 show forming a second contact opening 150 (FIG. 11) in second dielectric layer 126 to barrier layer 148 over first contact portion 120. This process may include any now known or later developed photolithography process such as depositing a photoresist 152 (FIG. 10), patterning the resist, and etching 154 (e.g., an oxide RIE) to barrier layer 148 to form second contact opening 150. A conventional etching 156 to remove the resist (FIG. 11) is next, followed by removing, e.g., by etching 158, barrier layer 148 in second contact opening 150 to expose, as shown in FIG. 12, first contact portion 120. In any event, second contact opening 150 has a width that is in the range of approximately 35 nm to approximately 150 nm.

FIG. 12 shows depositing a second liner layer 160 in second contact opening 150. Second liner layer 160 may include titanium nitride (TiN), tantalum nitride (TaN), tantalum (Ta) or titanium (Ti), and may have a thickness ranging from approximately 2 nm to approximately 15 nm.

FIG. 13 shows depositing a conductive material 162 to form second contact portion 124 in second contact opening 150 (FIG. 12). Conductive material 162 may be any metal, e.g., chemical vapor deposited (CVD) tungsten, copper plating, or other conductive material typically used for contacts. Conductive material 162 may be formed using any now known or later developed technique, e.g., for tungsten: deposit W, CMP W, etch back W, and etch TiN. Conductive material 162 may have a thickness in the range of approximately 20 nm to approximately 100 nm. First contact portion 120 is narrower than second contact portion 124. Second contact portion 124 may have a thickness in the range of approximately 25 nm to approximately 90 nm.

Contact 100, shown in FIG. 13, includes first contact portion 120 contacting silicide region 106. First contact portion having a width less than 100 nm. In addition, contact 100 includes second contact portion 124 coupled to first contact portion 120 from above, second contact portion 124 having a width greater than the width of first contact portion 120. Liner layer 160 of second contact portion 124 separates conductive material 162 of second contact portion 124 from first contact portion 120, but otherwise allows electrical interconnectivity such that first contact portion 120 and second contact portion 124 are electrically coupled and form contact 100.

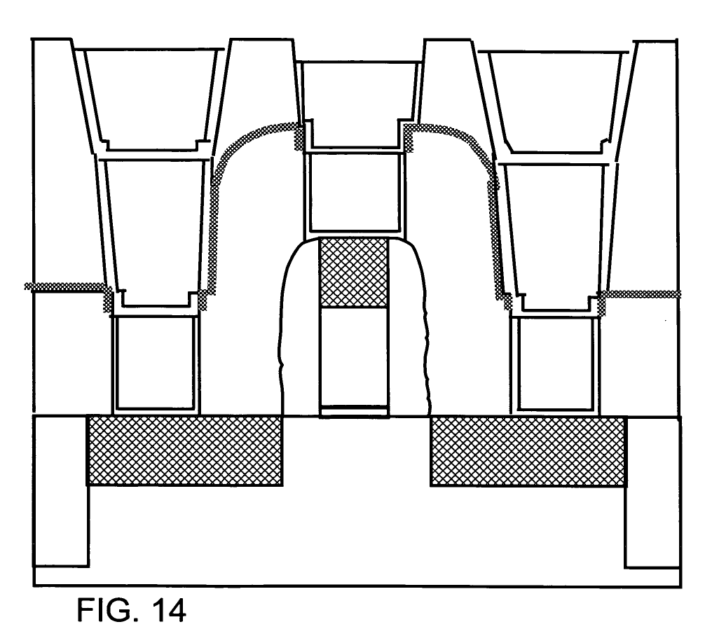

The processes described above may also be repeated such that, as shown in FIG. 14, more than two second contact portions are provided (shown for contacts to source/drain regions only). Each contact portion may be larger than one therebelow.

The above-described methods and resulting contact 100 allow for smaller contact size, and more layout flexibility. In addition, the processes are compatible with symmetric and asymmetric dual, intrinsically stressed liners. Furthermore, the processes allow for a reduction in a worst case aspect ratio (i.e., gate body height to contact bottom critical dimension) from the current 8.4 to approximately 5, and are achievable with current tooling.

The methods and structures as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method of forming a contact, the method comprising:
providing a device including a silicide region;
depositing a first dielectric layer over the device;
forming a first contact opening to the silicide region through the first dielectric layer;
depositing a first liner layer in the first contact opening;
depositing conductive material to form a first contact portion in the first contact opening;
etching to remove the first liner layer outside of the first contact opening;
depositing a barrier layer;
forming a second dielectric layer;
forming a second contact opening in the second dielectric layer to the barrier layer over the first contact portion;
removing the barrier layer in the second contact opening;
depositing a second liner layer in the second contact opening; and
depositing conductive material to form a second contact portion in the second contact opening.

2. The method of claim 1, wherein the first contact portion is narrower than the second contact portion.

3. The method of claim 2, wherein the first contact opening has a width that is in the range of approximately 20 nm to approximately 100 nm, and the second contact opening has a width that is in the range of approximately 35 nm to approximately 150 nm.

4. The method of claim 1, wherein the first dielectric layer includes silicon nitride (Si₃N₄), and the second dielectric layer includes silicon oxide (SiO₂).

5. The method of claim 1, wherein the first contact opening forming includes:
patterning a mask;
etching to form the first contact opening; and
removing the mask.

6. The method of claim 5, wherein the mask includes one of a photoresist or a hardmask layer under the photoresist.

7. The method of claim 1, wherein the first contact portion has a thickness in the range of approximately 15 nm to approximately 50 nm.

8. The method of claim 7, wherein the second contact portion has a thickness in the range of approximately 25 nm to approximately 90 nm.

9. The method of claim 1, wherein the barrier layer includes silicon nitride (Si₃N₄).

10. A contact comprising:
a first contact portion contacting a silicide region, the first contact portion having a width less than 100 nm; and
a second contact portion coupled to the first contact portion from above, the second contact portion having a width greater than the width of the first contact portion.

11. The contact of claim 10, wherein the first contact portion includes a liner layer separating a conductive material of the first contact portion from the second contact portion.

12. A method of forming a contact, the method comprising:
providing a device including a silicide region; and
forming a contact to the silicide region by:
first forming a lower contact portion to the silicide region through a first dielectric layer, and
second forming an upper contact portion to the lower contact portion through a second dielectric layer over the first dielectric layer.

13. The method of claim 12, wherein the first contact portion is narrower than the second contact portion.

14. The method of claim 13, wherein the first contact opening has a width that is in the range of approximately 30 nm to approximately 100 nm, and the second contact opening has a width that is in the range of approximately 35 nm to approximately 150 nm.

15. The method of claim 12, wherein the first dielectric layer includes silicon nitride (Si₃N₄), and the second dielectric layer includes silicon oxide (SiO₂).

16. The method of claim 12, wherein:
the first contact portion forming includes depositing a first dielectric layer over the device, forming a first contact opening to the silicide region through the first dielectric layer, depositing a first liner layer in the first contact opening, and depositing conductive material to form the first contact portion in the first contact opening; and
wherein the second contact portion forming includes etching to remove the first liner layer outside of the first contact opening, depositing a barrier layer, forming a second dielectric layer, forming a second contact opening in the second dielectric layer to the barrier layer over the first contact portion, removing the barrier layer in the second contact opening, depositing a second liner layer in the second contact opening, and
depositing conductive material to form the second contact portion in the second contact opening.

17. The method of claim 16, wherein the barrier layer includes silicon nitride (Si₃N₄).

18. The method of claim 16, wherein the first contact opening forming includes:
patterning a mask;
etching to form the first contact opening; and
removing the mask,
wherein the mask includes one of a photoresist or a hardmask layer over the photoresist.

19. The method of claim 12, wherein the first contact portion has a thickness in the range of approximately 15 nm to approximately 50 nm.

20. The method of claim 19, wherein the second contact portion has a thickness in the range of approximately 25 nm to approximately 90 nm.
